(19) United States
(12) Patent Application Publication
(10) Pub. No.: US 2009/0287446 A1
(43) Pub. Date: Nov. 19, 2009

(54) PHOTOVOLTAIC CELL REFERENCE MODULE FOR SOLAR TESTING

(75) Inventors: Dapeng Wang, Santa Clara, CA (US); Michel R. Frei, Palo Alto, CA (US); Tzay-Fa Su, San Jose, CA (US); David Tanner, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/428,195

(22) Filed: Apr. 22, 2009

Related U.S. Application Data
(60) Provisional application No. 61/048,498, filed on Apr. 28, 2008.

(51) Int. Cl. G06F 19/00; H01L 31/18; G01R 31/00

(52) U.S. Cl. 702/116; 438/73; 324/96; 257/E21.158

(57) ABSTRACT

The present invention generally includes an apparatus and method of forming a reference module device that is able to deliver a repeatable and desirable amount of power that does not degrade or change over time. The reference module can be used to help test and calibrate various testing equipment used in the production of a photovoltaic device that may be formed in a solar cell fab. The solar cell fab is generally an arrangement of processing modules and automation equipment that is used to form solar cell devices.

### CROSS-REFERENCE TO RELATED APPLICATIONS

This application claims benefit of U.S. provisional patent application Ser. No. 61/048,498, filed Apr. 28, 2008, which is herein incorporated by reference.

This application is related to U.S. application Ser. No. 12/351,087, filed Jan. 9, 2009, (Attorney Docket No. APPM/12962), U.S. application Ser. No. 12/202,199, filed Aug. 29, 2008 (Attorney Docket No. APPM/11141) and U.S. application Ser. No. 12/201,840, filed Aug. 29, 2008 (Attorney Docket No. APPM/11141.02).

### BACKGROUND OF THE INVENTION

1. Field of the Invention

Embodiments of the present invention generally relate to a design and a method of forming a device that is used to test a solar cell production process. Embodiments of the present invention also generally relate to an apparatus that uses the device to test and approve a solar cell device.

2. Description of the Related Art

Photovoltaic devices (PV), such as solar cells, are devices which convert light into direct current (DC) electrical power. Thin film silicon solar cells, or thin film PV cells, typically are formed on a substrate and have one or more p-i-n junctions. Each p-i-n junction comprises a p-type layer, an intrinsic type layer, and an n-type layer that are either amorphous, polycrystalline or microcrystalline materials. When the p-i-n junction of the PV cell is exposed to sunlight (consisting of energy from photons), the sunlight is converted to electricity through the PV effect. PV solar cells may be tiled into larger modules or arrays.

Typically, a thin film PV solar cell includes active regions and a transparent conductive oxide (TCO) film disposed as a front electrode and/or as a back electrode. The photoelectric conversion unit includes a p-type silicon layer, a n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si) and the like may be utilized to form the p-type, n-type, and/or i-type layers of the PV solar cell. The backside contact may contain one or more conductive layers.

To assure that solar cell devices formed in a solar cell production line meet desired power generation and efficiency standards, various tests are performed on each formed solar cell. In some cases, a dedicated solar cell qualification module is placed in the solar cell production line to qualify and test the output of the formed solar cells. Typically, in these qualification modules a light emitting source and solar cell probing device are used to measure the output of the formed solar cell. If the qualification module detects a defect in the formed device it can take corrective actions or the solar cell can be scrapped. However, to assure that the tests performed in the testing module are the same for every device that is tested, the qualification module must be calibrated and recalibrated from time to time. The calibration and recalibration process requires the use of a number of devices, which may include a reference solar cell that is used to qualify the output of the lamps and the environment of the testing module.

Generally, thin film solar cells are not used as a calibration standard since their efficiency and electrical output changes over time, thus affecting the reliability and accuracy of the solar cell calibration process. However, other more stable solar cells, such as crystalline silicon solar cells or III-V type solar cells, are not available in sizes required to reproduce the output of the often large thin film PV cells that are produced in a solar cell production line. Moreover, the absorption spectrum of these more stable types of solar cells are different than the thin film PV cells, thus also affecting the calibration accuracy and reliability of the results. Therefore, there is a need for a large surface area reference solar cell that is able to deliver a repeatable equivalent amount of power that does not degrade over time.

### SUMMARY OF THE INVENTION

In one embodiment of the present invention, a device used to qualify a solar cell testing module includes a substrate and a plurality of solar cells disposed over a surface of the substrate. The solar cell testing module also includes an optical filter disposed over at least one of the plurality of solar cells, wherein the optical filter is adapted to preferentially transmit a desired range of wavelengths of light.

In another embodiment of the invention, a device used to qualify a solar cell testing module includes a substrate and a plurality of solar cells disposed over a surface of the substrate. The solar cell testing module also includes a cover encapsulating the solar cells. The cover is also an optical filter that is adapted to preferentially transmit a desired range of wavelengths of light.

In another embodiment of the present invention, a system for qualifying solar cell devices includes a plurality of solar cell processing chambers that are adapted to form at least a portion of a solar cell device on a substrate, a solar simulator module having a testing assembly that is adapted to measure the electrical characteristics of a solar cell device formed on the substrate when exposed to a known amount of light delivered from a lamp, and a reference module that is used to calibrate the testing assembly. The reference module includes a substrate, a plurality of solar cells disposed over a surface of the substrate, and an optical filter disposed over at least one of the plurality of solar cells, wherein the optical filter is adapted to preferentially transmit a desired range of wavelengths of light.

In another embodiment of the present invention, a method of qualifying a solar cell testing process includes forming a first type of solar cell device, qualifying the electrical characteristics of the formed first type of solar cell device in a solar simulator module by measuring the electrical output of the first type of solar cell device when a known amount of optical energy is delivered to a surface of the first type of solar cell device, and forming a reference module. The reference module includes a substrate, two or more second type of solar cells disposed over a surface of the substrate, and an optical filter disposed over at least one of the two or more second type of solar cells. The method also includes qualifying the solar simulator by measuring the electrical output of the reference module when the same known amount of optical energy is delivered to a surface of the two or more second type of solar cells and comparing the measured result with a previous measured result performed using the reference module.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process sequence for forming a solar cell device according to one embodiment described herein.

FIG. 2 illustrates a plan view of a solar cell production line according to one embodiment described herein.

FIG. 3A is a side cross-sectional view of a thin film solar cell device according to one embodiment described herein.

FIG. 3B is a side cross-sectional view of a thin film solar cell device according to one embodiment described herein.

FIG. 3C is a plan view of a composite solar cell structure according to one embodiment described herein.

FIG. 3D is a side cross-sectional view along Section A-A of FIG. 3C.

FIG. 3E is a side cross-sectional view of a thin film solar cell device according to one embodiment described herein.

FIG. 4 is a schematic plan view of a solar simulator module according to one embodiment of the present invention.

FIG. 5A is a schematic, cross-sectional view of the solar simulator taken along line 5-5 of FIG. 4 depicting the positioning robot in a loading/unloading position.

FIG. 5 is a schematic, cross-sectional view of the solar simulator taken along line 5-5 of FIG. 4 depicting the positioning robot in a testing position.

FIG. 6 is an isometric view of a reference module according to one embodiment described herein.

FIG. 7A is a cross-sectional view of a reference module according to one embodiment described herein.

FIG. 7B is a cross-sectional view of a reference module according to one embodiment described herein.

FIG. 8 is a graph of quantum efficiency versus wavelength of various features and components that may be used in a reference cell according to one embodiment described herein.

FIG. 9 is a top view of a reference module according to one embodiment described herein.

FIG. 10 is a top view of a reference module according to one embodiment described herein.

### DETAILED DESCRIPTION

The present invention generally includes an apparatus and method of forming a reference module device that is able to deliver a repeatable and desirable amount of power that will not degrade or change over time. The reference module can be used to help test and calibrate various testing equipment used in the production of a photovoltaic device that may be formed in a solar cell fab.

The solar cell fab is generally an arrangement of automated processing modules and automation equipment used to form solar cell devices that are interconnected by an automated material handling system. In one embodiment, the fab is a fully automated solar cell device production line that is designed to reduce and/or remove the need for human interaction and/or labor intensive processing steps to improve the solar cell device reliability, process repeatability, and the cost of ownership of the formation process.

In one configuration, the solar cell fab or system is adapted to form functionally tested thin film solar cell devices from a single large substrate. In one embodiment, the system comprises a substrate receiving module adapted to accept an incoming substrate, one or more absorbing layer deposition cluster tools having at least one processing chamber adapted to deposit a silicon-containing layer on a processing surface of the substrate, one or more back contact deposition chambers adapted to deposit a back contact layer on the processing surface of the substrate, one or more material removal chambers adapted to remove material from the processing surface of each substrate, one or more sectioning modules to section the processed substrate into multiple smaller processed substrates, a solar cell encapsulation device, an autoclave module adapted to heat and expose a composite solar cell structure to a pressure greater than atmospheric pressure, a junction box attaching region to attach a connection element that allows the solar cells to be connected to external components, and one or more quality assurance modules adapted to test and qualify each completely formed solar cell device. In one embodiment, the one or more quality assurance modules include a horizontally oriented solar simulator for testing fully formed solar cell devices positioned in a vertical orientation.

While the formation of silicon thin film solar cell devices is primarily described herein, this configuration is not intended to be limiting to the scope of the invention since the apparatus and methods disclosed herein can also be used to form, test, and analyze other types of solar cell devices, such as III-V type solar cells, thin film chalcogenide solar cells (e.g., CIGS, CdTe cells), amorphous or nanocrystalline silicon solar cells, photochemical type solar cells (e.g., dye sensitized), crystalline silicon solar cells, organic type solar cells, or other similar solar cell devices.

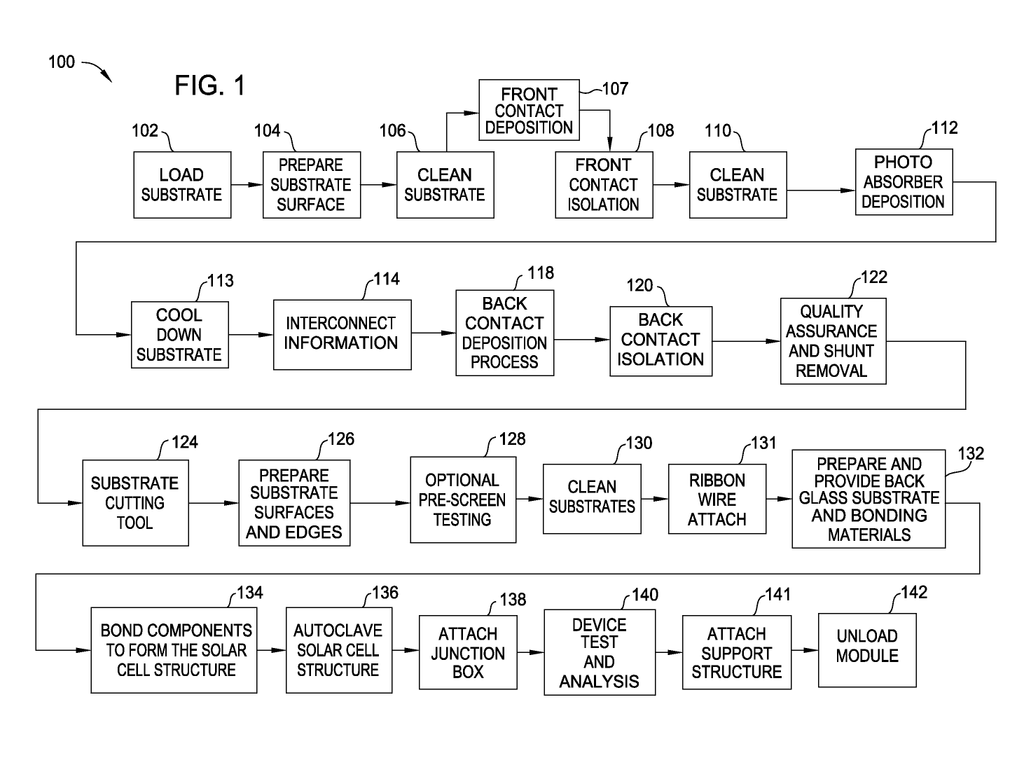

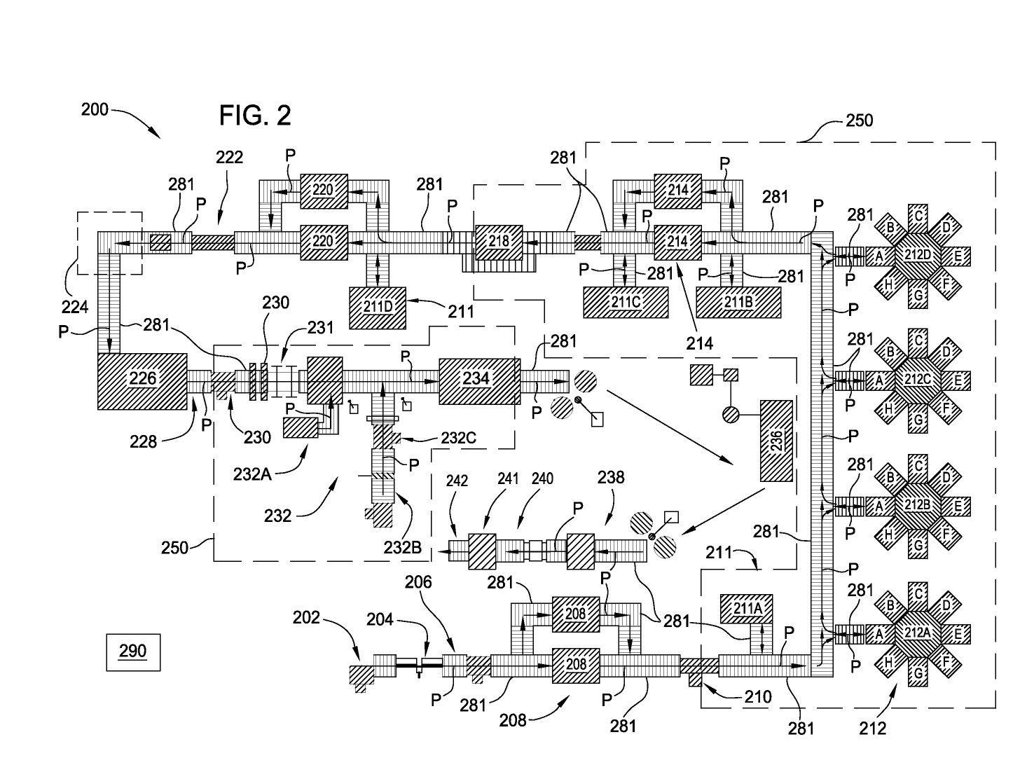

FIG. 1 illustrates one embodiment of a process sequence 100 that contains a plurality of steps (i.e., steps 102-142) that are each used to form a solar cell device using a novel solar cell production line 200 described herein. The configuration, number of processing steps, and order of the processing steps in the process sequence 100 is not intended to be limiting to the scope of the invention described herein. FIG. 2 is a plan view of one embodiment of the production line 200, which is intended to illustrate some of the typical processing modules and process flows through the system and other related aspects of the system design, and is thus not intended to be limiting to the scope of the invention described herein.

A system controller 290 may be used to control one or more components found in the solar cell production line 200. The system controller 290 facilitates the control and automation of the overall solar cell production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like.

A program (or computer instructions) readable by the system controller 290 determines which tasks are performable on a substrate. Preferably, the program is software readable by the system controller 290 that includes code to perform tasks relating to monitoring, moving, supporting, and/or positioning of a substrate along with various process recipe tasks and various chamber process recipe steps performed in the solar cell production line 200. In one embodiment, the system controller 290 also contains a plurality of programmable logic controllers (PLC's) that are used to locally control one or more modules in the solar cell production and a material handling system controller (e.g., PLC or standard computer) that deals with the higher level strategic moving, scheduling, and running of the complete solar cell production line.

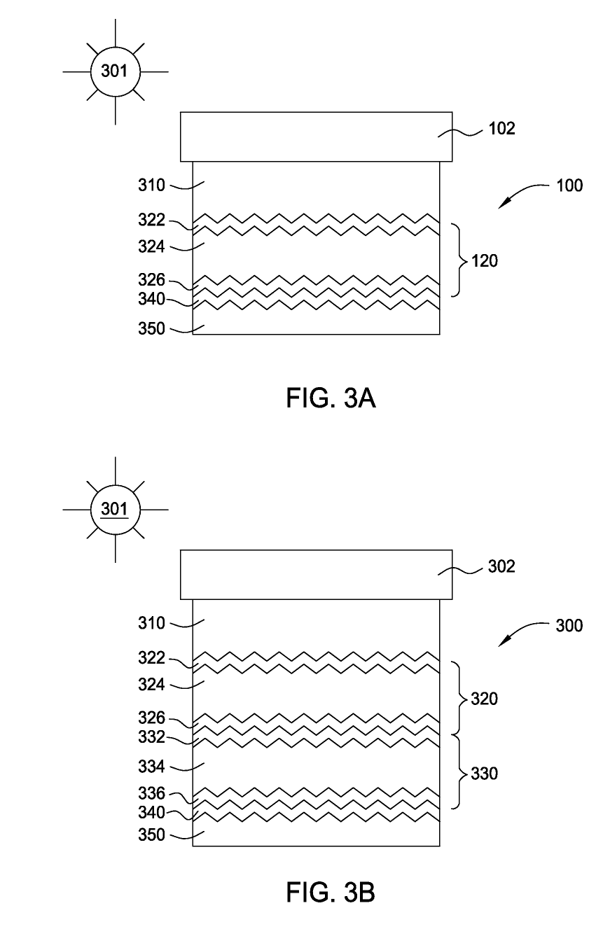

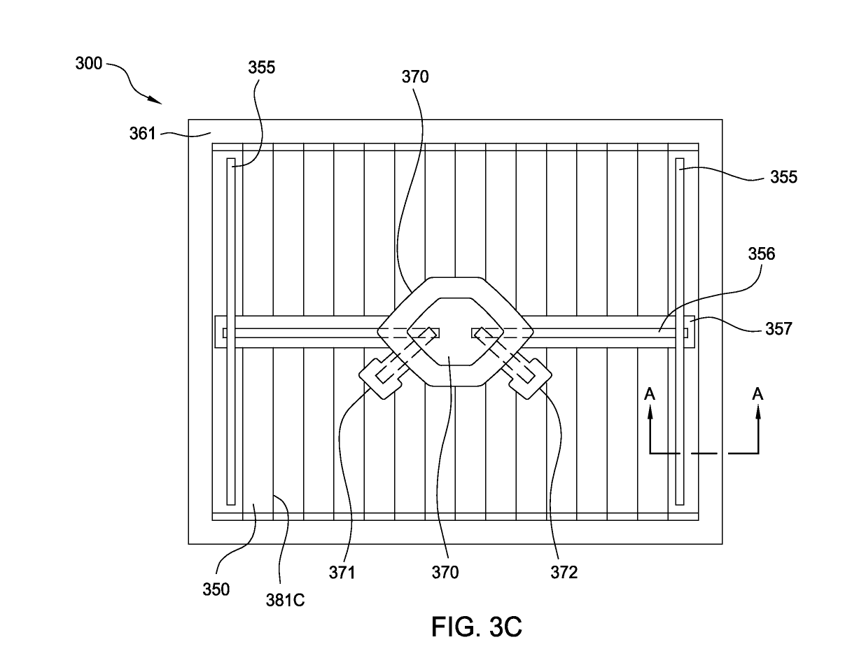

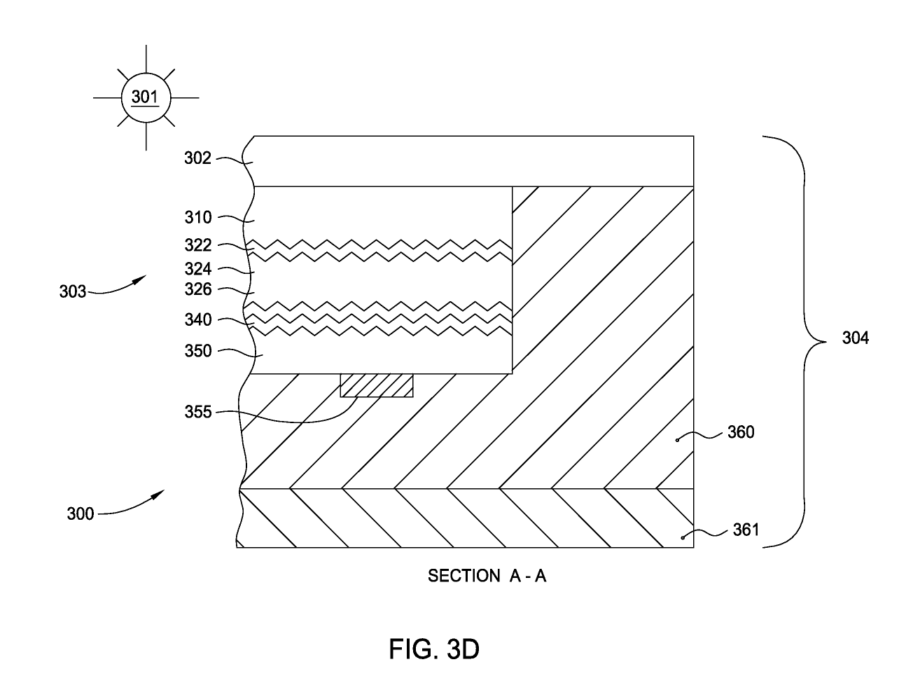

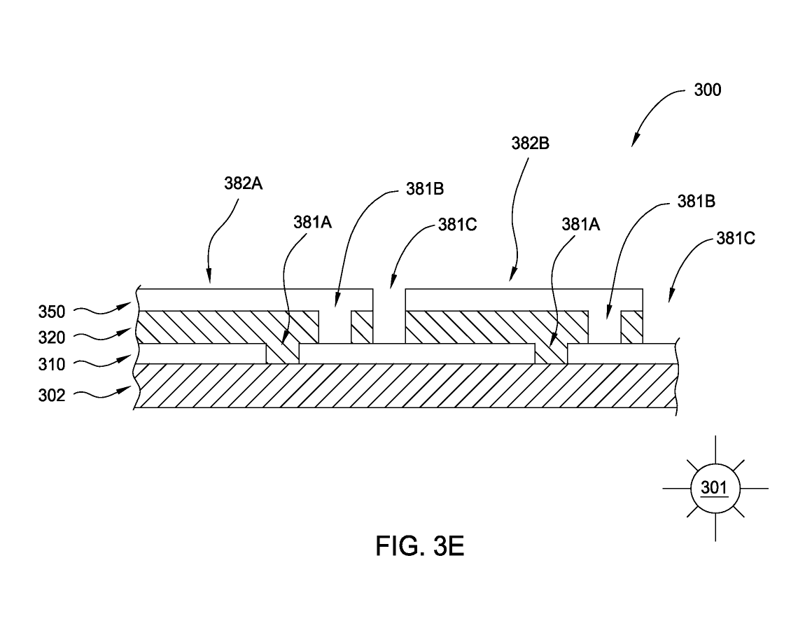

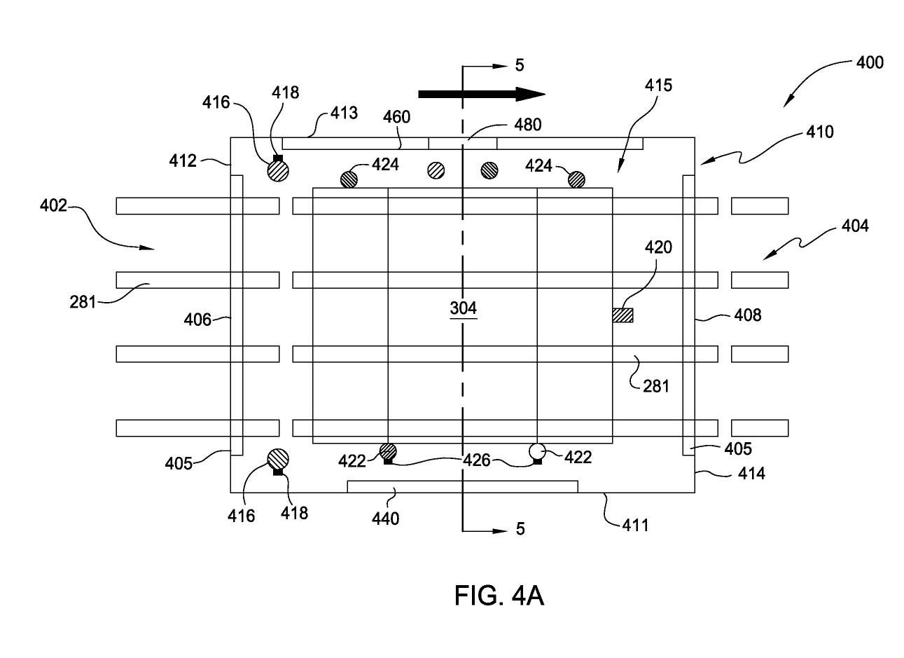

Examples of a solar cell 300 that can be formed and tested using the process sequences illustrated in FIG. 1 and the components illustrated in the solar cell production line 200 are illustrated in FIGS. 3A-3E. FIG. 3A is a simplified schematic diagram of a single junction amorphous or micro-crystalline silicon solar cell 300 that can be formed and analyzed in the system described below.

As shown in FIG. 3A, the single junction amorphous or micro-crystalline silicon solar cell 300 is oriented toward a light source or solar radiation 301. The solar cell 300 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 300 further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 3A, the first TCO layer 310 is textured, and the subsequent thin films deposited thereover generally follow the topography of the surface below it.

In one configuration, the first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å. The back contact layer 350 may include, but is not limited to, a material selected from the group consisting of Al, Ag, Ti, Cr, Au, Cu, Pt, alloys thereof, and combinations thereof.

FIG. 3B is a schematic diagram of an embodiment of a solar cell 300, which is a multi-junction solar cell that is oriented toward the light or solar radiation 301. The solar cell 300 comprises a substrate 302, such as a glass substrate, polymer substrate, metal substrate, or other suitable substrate, with thin films formed thereover. The solar cell 300 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340.

In the embodiment shown in FIG. 3B, the first TCO layer 310 is textured, and the subsequent thin films deposited thereover generally follow the topography of the surface below it. The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å.

The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to a material selected from the group consisting of Al, Ag, Ti, Cr, Au, Cu, Pt, alloys thereof, and combinations thereof.

FIG. 3C is a plan view that schematically illustrates an example of the rear surface of a formed solar cell 300 that has been produced and tested in the production line 200. FIG. 3D is a side cross-sectional view of a portion of the solar cell 300 illustrated in FIG. 3C (see section A-A). While FIG. 3D illustrates the cross-section of a single junction cell similar to the configuration described in FIG. 3A, this is not intended to be limiting as to the scope of the invention described herein.

As shown in FIGS. 3C and 3D, the solar cell 300 may contain a substrate 302, the solar cell device elements (e.g., reference numerals 310-350), one or more internal electrical connections (e.g., side buss 355, cross-buss 356), a layer of bonding material 360, a back glass substrate 361, and a junction box 370. The junction box 370 may generally contain two junction box terminals 371, 372 that are electrically connected to portions of the solar cell 300 through the side buss 355 and the cross-buss 356, which are in electrical communication with the back contact layer 350 and active regions of the solar cell 300. To avoid confusion relating to the actions specifically performed on the substrates 302 in the discussion below, a substrate 302 having one or more of the deposited layers (e.g., reference numerals 310-350) and/or one or more internal electrical connections (e.g., side buss 355, cross-buss 356) disposed thereon is generally referred to as a device substrate 303. Similarly, a device substrate 303 that has been bonded to a back glass substrate 361 using a bonding material 360 is referred to as a composite solar cell structure 304.

FIG. 3E is a schematic cross-section of a solar cell 300 illustrating various scribed regions used to form the individual cells 382A-382B within the solar cell 300. As illustrated in FIG. 3E, the solar cell 300 includes a transparent substrate 302, a first TCO layer 310, a first p-i-n junction 320, and a back contact layer 350. Three laser scribing steps may be performed to produce trenches 381A, 381B, and 381C, which are generally required to form a high efficiency solar cell device. Although formed together on the substrate 302, the individual cells 382A and 382B are isolated from each other by the insulating trench 381C formed in the back contact layer 350 and the first p-i-n junction 320. In addition, the trench 381B is formed in the first p-i-n junction 320 so that the back contact layer 350 is in electrical contact with the first TCO layer 310. In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. While a single junction type solar cell is illustrated in FIG. 3E this configuration is not intended to be limiting to the scope of the invention described herein.

### General Solar Cell Formation Process Sequence

Referring to FIGS. 1 and 2, the process sequence 100 generally starts at step 102 in which a substrate 302 is loaded into the loading module 202 found in the solar cell production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar device and thus reduces the solar cell device cost, facilities costs, and production costs of the finally formed solar cell device. However, typically, it is advantageous to receive “raw” substrates 302 that have a transparent conducting oxide (TCO) layer (e.g., first TCO layer 310) already deposited on a surface of the substrate 302 before it is received into the system in step 102. If a conductive layer, such as TCO layer, is not deposited on the surface of the “raw” substrates then a front contact deposition step (step 107), which is discussed below, needs to be performed on a surface of the substrate 302.

In one embodiment, the substrates 302 or 303 are loaded into the solar cell production line 200 in a sequential fashion, and thus do not use a cassette or batch style substrate loading system. A cassette style and/or batch loading type system that requires the substrates to be un-loaded from the cassette, processed, and then returned to the cassette before moving to the next step in the process sequence can be time consuming and decrease the solar cell production line throughput. The use of batch processing does not facilitate certain embodiments of the present invention, such as fabricating multiple solar cell devices from a single substrate. Additionally, the use of a batch style process sequence generally prevents the use of an asynchronous flow of substrates through the production line, which may provide improved substrate throughput during steady state processing and when one or more modules are brought down for maintenance or due to a fault condition. Generally, batch or cassette based schemes are not able to achieve the throughput of the production line described herein, when one or more processing modules are brought down for maintenance, or even during normal operation, since the queuing and loading of substrates can require a significant amount of overhead time.

In the next step, step 104, the surfaces of the substrate 302 are prepared to prevent yield issues later on in the process. In one embodiment of step 104, the substrate is inserted into a front end substrate seaming module 204 that is used to prepare the edges of the substrate 302 or 303 to reduce the likelihood of damage, such as chipping or particle generation from occurring during the subsequent processes. Damage to the substrate 302 or 303 can affect device yield and the cost to produce a usable solar cell device. In one embodiment, the front end seaming module 204 is used to round or bevel the edges of the substrate 302 or 303. In one embodiment, a diamond impregnated belt or disc is used to grind the material from the edges of the substrate 302 or 303. In another embodiment, a grinding wheel, grit blasting, or laser ablation technique is used to remove the material from the edges of the substrate 302 or 303.

Next the substrate 302 or 303 is transported to the cleaning module 206, in which step 106, or a substrate cleaning step, is performed on the substrate 302 or 303 to remove any contaminants found on the surface of thereof. Common contaminants may include materials deposited on the substrate 302 or 303 during the substrate forming process (e.g., glass manufacturing process) and/or during shipping or storing of the substrates 302 or 303. Typically, the cleaning module 206 uses wet chemical scrubbing and rinsing steps to remove any undesirable contaminants.

In one example, the process of cleaning the substrate 302 or 303 may occur as follows. First, the substrate 302 or 303 enters a contaminant removal section of the cleaning module 206 from either a transfer table or an automation device 281. In general, the system controller 290 establishes the timing for each substrate 302 or 303 that enters the cleaning module 206. The contaminant removal section may utilize dry cylindrical brushes in conjunction with a vacuum system to dislodge and extract contaminants from the surface of the substrate 302. Next, a conveyor within the cleaning module 206 transfers the substrate 302 or 303 to a pre-rinse section, where spray tubes dispense hot DI water at a temperature, for example, of 50° C. from a DI water heater onto a surface of the substrate 302 or 303. Commonly, since the device substrate 303 has a TCO layer disposed thereon, and since TCO layers are generally electron absorbing materials, DI water is used to avoid any traces of possible contamination and ionizing of the TCO layer. Next, the rinsed substrate 302, 303 enters a wash section. In the wash section, the substrate 302 or 303 is wet-cleaned with a brush (e.g., perlon) and hot water. In some cases a detergent (e.g., Alconox™, Citrajet™, Detojet™, Transene™, and Basic H™), surfactant, pH adjusting agent, and other cleaning chemistries are used to clean and remove unwanted contaminants and particles from the substrate surface. A water re-circulation system recycles the hot water flow. Next, in a final rinse section of the cleaning module 206, the substrate 302 or 303 is rinsed with water at ambient temperature to remove any traces of contaminants. Finally, in a drying section, an air blower is used to dry the substrate 302 or 303 with hot air. In one configuration a deionization bar is used to remove the electrical charge from the substrate 302 or 303 at the completion of the drying process.

In the next step, or step 108, separate cells are electrically isolated from one another via scribing processes. Contamination particles on the TCO surface and/or on the bare glass surface can interfere with the scribing procedure. In laser scribing, for example, if the laser beam runs across a particle, it may be unable to scribe a continuous line, resulting in a short circuit between cells. In addition, any particulate debris present in the scribed pattern and/or on the TCO of the cells after scribing can cause shunting and non-uniformities between layers. Therefore, a well-defined and well-maintained process is generally needed to ensure that contamination is removed throughout the production process. In one embodiment, the cleaning module 206 is available from the Energy and Environment Solutions division of Applied Materials in Santa Clara, Calif.

Referring to FIGS. 1 and 2, in one embodiment, prior to performing step 108 the substrates 302 are transported to a front end processing module (not illustrated in FIG. 2) in which a front contact formation process, or step 107, is performed on the substrate 302. In one embodiment, the front end processing module is similar to the processing module 218 discussed below. In step 107, the one or more substrate front contact formation steps may include one or more preparation, etching, and/or material deposition steps to form the front contact regions on a bare solar cell substrate 302. In one embodiment, step 107 comprises one or more PVD steps that are used to form the front contact region on a surface of the substrate 302. In one embodiment, the front contact region contains a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact region. In another embodiment, one or more CVD steps are used to form the front contact region on a surface of the substrate 302.

Next the device substrate 303 is transported to the scribe module 208 in which step 108, or a front contact isolation step, is performed on the device substrate 303 to electrically isolate different regions of the device substrate 303 surface from each other. In step 108, material is removed from the device substrate 303 surface by use of a material removal step, such as a laser ablation process. The success criteria for step 108 are to achieve good cell-to-cell and cell-to-edge isolation while minimizing the scribe area.

In one embodiment, a Nd:vanadate (Nd:YVO₄) laser source is used ablate material from the device substrate 303 surface to form lines that electrically isolate one region of the device substrate 303 from the next. In one embodiment, the laser scribe process performed during step 108 uses a 1064 nm wavelength pulsed laser to pattern the material disposed on the substrate 302 to isolate each of the individual cells (e.g., individual cells 382A and 382B) that make up the solar cell 300. In one embodiment, a 5.7 m² substrate laser scribe module available from Applied Materials, Inc. of Santa Clara, Calif. is used to provide simple reliable optics and substrate motion for accurate electrical isolation of regions of the device substrate 303 surface. In another embodiment, a water jet cutting tool or diamond scribe is used to isolate the various regions on the surface of the device substrate 303.

It may be desirable to assure that the temperature of the device substrates 303 entering the scribe module 208 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the device substrate 303 temperature to about 25+/−0.5° C.

Next the device substrate 303 is transported to the cleaning module 210 in which step 110, or a pre-deposition substrate cleaning step, is performed on the device substrate 303 to remove any contaminants found on the surface of the device substrate 303 after performing the cell isolation step (step 108). Typically, the cleaning module 210 uses wet chemical scrubbing and rinsing steps to remove any undesirable contaminants found on the device substrate 303 surface after performing the cell isolation step. In one embodiment, a cleaning process similar to the processes described in step 106 above is performed on the device substrate 303 to remove any contaminants on the surface(s) of the device substrate 303.

Next, the device substrate 303 is transported to the processing module 212 in which step 112, which comprises one or more photoabsorber deposition steps, is performed on the device substrate 303. In step 112, the one or more photoabsorber deposition steps may include one or more preparation, etching, and/or material deposition steps that are used to form the various regions of the solar cell device. Step 112 generally comprises a series of sub-processing steps that are used to form one or more p-i-n junctions. In one embodiment, the one or more p-i-n junctions comprise amorphous silicon and/or microcrystalline silicon materials. In general, the one or more processing steps are performed in one or more cluster tools (e.g., cluster tools 212A-212D) found in the processing module 212 to form one or more layers in the solar cell device formed on the device substrate 303. In one embodiment, the device substrate 303 is transferred to an accumulator 211A prior to being transferred to one or more of the cluster tools 212A-212D. In one embodiment, in cases where the solar cell device is formed to include multiple junctions, such as the tandem junction solar cell 300 illustrated in FIG. 3B, the cluster tool 212A in the processing module 212 is adapted to form the first p-i-n junction 320 and cluster tools 212B-212D are configured to form the second p-i-n junction 330.

In one embodiment of the process sequence 100, a cool down step, or step 113, is performed after step 112 has been performed. The cool down step is generally used to stabilize the temperature of the device substrate 303 to assure that the processing conditions seen by each device substrate 303 in the subsequent processing steps are repeatable. Generally, the temperature of the device substrate 303 exiting the processing module 212 could vary by many degrees Celsius and exceed a temperature of 50° C., which can cause variability in the subsequent processing steps and solar cell performance.

In one embodiment, the cool down step 113 is performed in one or more of the substrate supporting positions found in one or more accumulators 211. In one configuration of the production line, as shown in FIG. 2, the processed device substrates 303 may be positioned in one of the accumulators 211B for a desired period of time to control the temperature of the device substrate 303. In one embodiment, the system controller 290 is used to control the positioning, timing, and movement of the device substrates 303 through the accumulator(s) 211 to control the temperature of the device substrates 303 before proceeding down stream through the production line.

Next, the device substrate 303 is transported to the scribe module 214 in which step 114, or the interconnect formation step, is performed on the device substrate 303 to electrically isolate various regions of the device substrate 303 surface from each other. In step 114, material is removed from the device substrate 303 surface by use of a material removal step, such as a laser ablation process. In one embodiment, an Nd:vanadate (Nd:YVO₄) laser source is used ablate material from the substrate surface to form lines that electrically isolate one solar cell from the next. In one embodiment, a 5.7 m² substrate laser scribe module available from Applied Materials, Inc. is used to perform the accurate scribing process. In one embodiment, the laser scribe process performed during step 108 uses a 532 nm wavelength pulsed laser to pattern the material disposed on the device substrate 303 to isolate the individual cells that make up the solar cell 300. As shown in FIG. 3E, in one embodiment, the trench 381B is formed in the first p-i-n junction 320 layers by use of a laser scribing process. In another embodiment, a water jet cutting tool or diamond scribe is used to isolate the various regions on the surface of the solar cell.

It may be desirable to assure that the temperature of the device substrates 303 entering the scribe module 214 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the substrate temperature to about 25+/−0.5° C.

In one embodiment, the solar cell production line 200 has at least one accumulator 211 positioned after the scribe module(s) 214. During production accumulators 211C may be used to provide a ready supply of substrates to the processing module 218, and/or provide a collection area where substrates coming from the processing module 212 can be stored if the processing module 218 goes down or can not keep up with the throughput of the scribe module(s) 214. In one embodiment it is generally desirable to monitor and/or actively control the temperature of the substrates exiting the accumulators 211C to assure that the results of the back contact formation step 120 are repeatable. In one aspect, it is desirable to assure that the temperature of the substrates exiting the accumulators 211C or arriving at the processing module 218 are at a temperature in a range between about 20° C. and about 26° C. In one embodiment, it is desirable to control the substrate temperature to about 25+/−0.5° C. In one embodiment, it is desirable to position one or more accumulators 211C that are able to retain at least about 80 substrates.

Next, the device substrate 303 is transported to the processing module 218 in which one or more substrate back contact formation steps, or step 118, are performed on the device substrate 303. In step 118, the one or more substrate back contact formation steps may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from a group consisting of zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 305. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the device substrate 303.

In one embodiment, the solar cell production line 200 has at least one accumulator 211 positioned after the processing module 218. During production, the accumulators 211D may be used to provide a ready supply of substrates to the scribe modules 220, and/or provide a collection area where substrates coming from the processing module 218 can be stored if the scribe modules 220 go down or can not keep up with the throughput of the processing module 218. In one embodiment it is generally desirable to monitor and/or actively control the temperature of the substrates exiting the accumulators 211D to assure that the results of the back contact formation step 120 are repeatable. In one aspect, it is desirable to assure that the temperature of the substrates exiting the accumulators 211D or arriving at the scribe module 220 are at a temperature in a range between about 20° C. and about 26° C. In one embodiment, it is desirable to control the substrate temperature to about 25+/−0.5° C. In one embodiment, it is desirable to position one or more accumulators 211C that are able to retain at least about 80 substrates.

Next, the device substrate 303 is transported to the scribe module 220 in which step 120, or a back contact isolation step, is performed on the device substrate 303 to electrically isolate the plurality of solar cells contained on the substrate surface from each other. In step 120, material is removed from the substrate surface by use of a material removal step, such as a laser ablation process. In one embodiment, a Nd:vanadate (Nd:YVO₄) laser source is used ablate material from the device substrate 303 surface to form lines that electrically isolate one solar cell from the next. In one embodiment, a 5.7 m² substrate laser scribe module, available from Applied Materials, Inc., is used to accurately scribe the desired regions of the device substrate 303. In one embodiment, the laser scribe process performed during step 120 uses a 532 nm wavelength pulsed laser to pattern the material disposed on the device substrate 303 to isolate the individual cells that make up the solar cell 300. As shown in FIG. 3E, in one embodiment, the trench 381C is formed in the first p-i-n junction 320 and back contact layer 350 by use of a laser scribing process.

It may be desirable to assure that the temperature of the device substrates 303 entering the scribe module 220 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the substrate temperature to about 25+/−0.5° C.

Next, the device substrate 303 is transported to the quality assurance module 222 in which step 122, or quality assurance and/or shunt removal steps, are performed on the device substrate 303 to assure that the devices formed on the substrate surface meet a desired quality standard and in some cases correct defects in the formed device. In step 122, a probing device is used to measure the quality and material properties of the formed solar cell device by use of one or more substrate contacting probes.

In one embodiment, the quality assurance module 222 projects a low level of light at the p-i-n junction(s) of the solar cell and uses the one more probes to measure the output of the cell to determine the electrical characteristics of the formed solar cell device(s). If the module detects a defect in the formed device, it can take corrective actions to fix the defects in the formed solar cells on the device substrate 303. In one embodiment, if a short or other similar defect is found, it may be desirable to create a reverse bias between regions on the substrate surface to control and or correct one or more of the defectively formed regions of the solar cell device. During the correction process the reverse bias generally delivers a voltage high enough to cause the defects in the solar cells to be corrected. In one example, if a short is found between supposedly isolated regions of the device substrate 303 the magnitude of the reverse bias may be raised to a level that causes the conductive elements in areas between the isolated regions to change phase, decompose, or become altered in some way to eliminate or reduce the magnitude of the electrical short.

In one embodiment of the process sequence 100, the quality assurance module 222 and factory automation system are used together to resolve quality issues found in a formed device substrate 303 during the quality assurance testing. In one case, a device substrate 303 may be sent back upstream in the processing sequence to allow one or more of the fabrication steps to be re-performed on the device substrate 303 (e.g., back contact isolation step (step 120)) to correct one or more quality issues with the processed device substrate 303.

Next, the device substrate 303 is optionally transported to the substrate sectioning module 224 in which a substrate sectioning step 124 is used to cut the device substrate 303 into a plurality of smaller device substrates 303 to form a plurality of smaller solar cell devices. In one embodiment of step 124, the device substrate 303 is inserted into substrate sectioning module 224 that uses a CNC glass cutting tool to accurately cut and section the device substrate 303 to form solar cell devices that are a desired size. In one embodiment, the device substrate 303 is inserted into the cutting or substrate sectioning module 224 that uses a glass scribing tool to accurately score the surface of the device substrate 303. The device substrate 303 is then broken along the scored lines to produce the desired size and number of sections needed for the completion of the solar cell devices.

In one embodiment, steps 102-122 can be configured to use equipment that is adapted to perform process steps on large device substrates 303, such as 2200 mm×2600 mm×3 mm glass device substrates 303, and steps 124 onward can be adapted to fabricate various smaller sized solar cell devices with no additional equipment required. In another embodiment, step 124 is positioned in the process sequence 100 prior to step 122 so that the initially large device substrate 303 can be sectioned to form multiple individual solar cells that are then tested and characterized one at a time or as a group (i.e., two or more at a time). In this case, steps 102-121 are configured to use equipment that is adapted to perform process steps on large device substrates 303, such as 2200 mm×2600 mm×3 mm glass substrates, and steps 124 and 122 onward are adapted to fabricate various smaller sized modules with no additional equipment required.

Referring back to FIGS. 1 and 2, the device substrate 303 is next transported to the seamer/edge deletion module 226 in which a substrate surface and edge preparation step 126 is used to prepare various surfaces of the device substrate 303 to prevent yield issues later on in the process. In one embodiment of step 126, the device substrate 303 is inserted into seamer/edge deletion module 226 to prepare the edges of the device substrate 303 to shape and prepare the edges of the device substrate 303. Damage to the device substrate 303 edge can affect the device yield and the cost to produce a usable solar cell device. In another embodiment, the seamer/edge deletion module 226 is used to remove deposited material from the edge of the device substrate 303 (e.g., 10 mm) to provide a region that can be used to form a reliable seal between the device substrate 303 and the backside glass (i.e., steps 134-136 discussed below). Material removal from the edge of the device substrate 303 may also be useful to prevent electrical shorts in the final formed solar cell.

In one embodiment, a diamond impregnated belt is used to grind the deposited material from the edge regions of the device substrate 303. In another embodiment, a grinding wheel is used to grind the deposited material from the edge regions of the device substrate 303. In another embodiment, dual grinding wheels are used to remove the deposited material from the edge of the device substrate 303. In yet another embodiment, grit blasting or laser ablation techniques are used to remove the deposited material from the edge of the device substrate 303. In one aspect, the seamer/edge deletion module 226 is used to round or bevel the edges of the device substrate 303 by use of shaped grinding wheels, angled and aligned belt sanders, and/or abrasive wheels.

Next the device substrate 303 is transported to the pre-screen module 228 in which optional pre-screen steps 128 are performed on the device substrate 303 to assure that the devices formed on the substrate surface meet a desired quality standard. In step 128, a light emitting source and probing device are used to measure the output of the formed solar cell device by use of one or more substrate contacting probes. If the module 228 detects a defect in the formed device it can take corrective actions or the solar cell can be scrapped.

Next the device substrate 303 is transported to the cleaning module 230 in which step 130, or a pre-lamination substrate cleaning step, is performed on the device substrate 303 to remove any contaminants found on the surface of the substrates 303 after performing steps 122-128. Typically, the cleaning module 230 uses wet chemical scrubbing and rinsing steps to remove any undesirable contaminants found on the substrate surface after performing the cell isolation step. In one embodiment, a cleaning process similar to the processes described in step 106 is performed on the device substrate 303 to remove any contaminants on the surface(s) of the device substrate 303.

Next the device substrate 303 is transported to a bonding wire attach module 231 in which step 131, or a bonding wire attach step, is performed on the substrate device 303. Step 131 is used to attach the various wires/leads required to connect the various external electrical components to the formed solar cell device. Typically, the bonding wire attach module 231 is an automated wire bonding tool that reliably and quickly forms the numerous interconnects that are often required to form the large solar cells formed in the production line 200.

In one embodiment, the bonding wire attach module 231 is used to form the side-buss 355 (FIG. 3C) and cross-buss 356 on the formed back contact region (step 118). In this configuration the side-buss 355 may be a conductive material that can be affixed, bonded, and/or fused to the back contact layer 350 found in the back contact region to form a good electrical contact. In one embodiment, the side-buss 355 and cross-buss 356 each comprise a metal strip, such as copper tape, a nickel coated silver ribbon, a silver coated nickel ribbon, a tin coated copper ribbon, a nickel coated copper ribbon, or other conductive material that can carry the current delivered by the solar cell and be reliably bonded to the metal layer in the back contact region. In one embodiment, the metal strip is between about 2 mm and about 10 mm wide and between about 1 mm and about 3 mm thick.

The cross-buss 356, which is electrically connected to the side-buss 355 at the junctions, can be electrically isolated from the back contact layer(s) of the solar cell by use of an insulating material 357, such as an insulating tape. The ends of each of the cross-busses 356 generally have one or more leads that are used to connect the side-buss 355 and the cross-buss 356 to the electrical connections found in a junction box 370, which is used to connect the formed solar cell to the other external electrical components.

In the next step, step 132, a bonding material 360 (FIG. 3D) and “back glass” substrate 361 are prepared for delivery into the solar cell formation process (i.e., process sequence 100). The preparation process is performed in the glass lay-up module 232, which comprises a material preparation module 232A, a glass loading module 232B, and a glass cleaning module 232C. The back glass substrate 361 is bonded onto the device substrate 303 formed in steps 102-130 above by use of a laminating process (step 134 discussed below). In one embodiment of step 132, a polymeric material is prepared to be placed between the back glass substrate 361 and the deposited layers on the device substrate 303 to form a hermetic seal to prevent the environment from attacking the solar cell during its life.

Referring to FIG. 2, step 132 comprises a series of sub-steps in which a bonding material 360 is prepared in the material preparation module 232A, the bonding material 360 is then placed over the device substrate 303, the back glass substrate 361 is loaded into the loading module 232B and washed by the cleaning module 232C, and the back glass substrate 361 is then placed over the bonding material 360 and the device substrate 303.

In one embodiment, the material preparation module 232A is adapted to receive the bonding material 360 in a sheet form and perform one or more cutting operations to provide a bonding material, such as Polyvinyl Butyral (PVB) or Ethylene Vinyl Acetate (EVA) sized to form a reliable seal between the backside glass and the solar cells formed on the device substrate 303. In general, when using bonding materials 360 that are polymeric, it is desirable to control the temperature (e.g., 16-18° C.) and relative humidity (e.g., RH 20-22%) of the solar cell production line 200 where the bonding material 360 is stored and integrated into the solar cell device to assure that the attributes of the bond formed in the bonding module 234 are repeatable and the dimensions of the polymeric material are stable. It is generally desirable to store the bonding material prior to use in temperature and humidity controlled area (e.g., T=6-8° C.; RH=20-22%).

The tolerance stack up of the various components in the bonded device (Step 134) can be an issue when forming large solar cells. Therefore, accurate control of the bonding material properties and tolerances of the cutting process assure that a reliable hermetic seal is formed. In one embodiment, PVB may be used to advantage due to its UV stability, moisture resistance, thermal cycling, good US fire rating, compliance with Intl Building Code, low cost, and reworkable thermoplastic properties.

In one part of step 132, the bonding material 360 is transported and positioned over the back contact layer 350, the side-buss 355 (FIG. 3C), and the cross-buss 356 (FIG. 3C) elements of the device substrate 303 using an automated robotic device. The device substrate 303 and bonding material 360 are then positioned to receive a back glass substrate 361, which can be placed thereon by use of the same automated robotic device used to position the bonding material 360, or a second automated robotic device.

In one embodiment, prior to positioning the back glass substrate 361 over the bonding material 360, one or more preparation steps are performed to the back glass substrate 361 to assure that subsequent sealing processes and final solar product are desirably formed. In one case, the back glass substrate 361 is received in a “raw” state where the edges, overall size, and/or cleanliness of the substrate 361 are not well controlled. Receiving “raw” substrates reduces the cost to prepare and store substrates prior to forming a solar device and thus reduces the solar cell device cost, facilities costs, and production costs of the finally formed solar cell device. In one embodiment of step 132, the back glass substrate 361 surfaces and edges are prepared in a seaming module (e.g., seamer 204) prior to performing the back glass substrate cleaning step. In the next sub-step of step 132, the back glass substrate 361 is transported to the cleaning module 232C in which a substrate cleaning step is performed on the substrate 361 to remove any contaminants found on the surface of the substrate 361. Common contaminants may include materials deposited on the substrate 361 during the substrate forming process (e.g., glass manufacturing process) and/or during shipping of the substrates 361. Typically, the cleaning module 232C uses wet chemical scrubbing and rinsing steps to remove any undesirable contaminants as discussed above. The prepared back glass substrate 361 is then positioned over the bonding material and the device substrate 303 by use of an automated robotic device.

Next the device substrate 303, the back glass substrate 361, and the bonding material 360 are transported to the bonding module 234 in which step 134, or lamination steps are performed to bond the backside glass substrate 361 to the device substrate formed in steps 102-130 discussed above. In step 134, a bonding material 360, such as Polyvinyl Butyral (PVB) or Ethylene Vinyl Acetate (EVA), is sandwiched between the backside glass substrate 361 and the device substrate 303. Heat and pressure are applied to the structure to form a bonded and sealed device using various heating elements and other devices found in the bonding module 234. The device substrate 303, the back glass substrate 361, and the bonding material 360 thus form a composite solar cell structure 304 (FIG. 3D) that at least partially encapsulates the active regions of the solar cell device. In one embodiment, at least one hole formed in the back glass substrate 361 remains at least partially uncovered by the bonding material 360 to allow portions of the cross-buss 356 or the side buss 355 to remain exposed so that electrical connections can be made to these regions of the solar cell structure 304 in future steps (i.e., step 138).

Next the composite solar cell structure 304 is transported to the autoclave module 236 in which step 136, or autoclave steps are performed on the composite solar cell structure 304 to remove trapped gasses in the bonded structure and assure that a good bond is formed during step 134. In step 134, a bonded solar cell structure 304 is inserted in the processing region of the autoclave module where heat and high pressure gases are delivered to reduce the amount of trapped gas and improve the properties of the bond between the device substrate 303, back glass substrate, and bonding material 360. The processes performed in the autoclave are also useful to assure that the stress in the glass and bonding layer (e.g., PVB layer) are more controlled to prevent future failures of the hermetic seal or failure of the glass due to the stress induced during the bonding/lamination process. In one embodiment, it may be desirable to heat the device substrate 303, back glass substrate 361, and bonding material 360 to a temperature that causes stress relaxation in one or more of the components in the formed solar cell structure 304.

Next the solar cell structure 304 is transported to the junction box attachment module 238 in which junction box attachment steps 138 are performed on the formed solar cell structure 304. The junction box attachment module 238, used during step 138, is used to install a junction box 370 (FIG. 3C) on a partially formed solar cell. The installed junction box 370 acts as an interface between the external electrical components that will connect to the formed solar cell, such as other solar cells or a power grid, and the internal electrical connections points, such as the leads, formed during step 131. In one embodiment, the junction box 370 contains one or more junction box terminals 371, 372 so that the formed solar cell can be easily and systematically connected to other external devices to deliver the generated electrical power.

Next the solar cell structure 304 is transported to the device testing module 240 in which device screening and analysis steps 140 are performed on the solar cell structure 304 to assure that the devices formed on the solar cell structure 304 surface meet desired quality standards. In one embodiment, the device testing module 240 is a solar simulator module that is used to qualify and test the output of the one or more formed solar cells. In step 140, a light emitting source and probing device are used to measure the output of the formed solar cell device by use of one or more automated components adapted to make electrical contact with terminals in the junction box 370. If the module detects a defect in the formed device it can take corrective actions or the solar cell can be scrapped. A more detailed description of the device testing module 240 is presented below in the section entitled “Solar Simulator Module Design and Processes.”

Next the solar cell structure 304 is transported to the support structure module 241 in which support structure mounting steps 141 are performed on the solar cell structure 304 to provide a complete solar cell device that has one or more mounting elements attached to the solar cell structure 304 formed using steps 102-140 to a complete solar cell device that can easily be mounted and rapidly installed at a customer's site.

Next the solar cell structure 304 is transported to the unload module 242 in which step 142, or device unload steps are performed on the substrate to remove the formed solar cells from the solar cell production line 200.

In one embodiment of the solar cell production line 200, one or more regions in the production line are positioned in a clean room environment to reduce or prevent contamination from affecting the solar cell device yield and useable lifetime. In one embodiment, as shown in FIG. 2, a class 10,000 clean room space 250 is placed around the modules used to perform steps 108-118 and steps 130-134.

### Solar Simulator Module Design and Processes

In one embodiment, the device testing module 240 comprises a solar simulator module for qualifying and testing the output of the one or more formed solar cell structures 304, such as solar cell 300 depicted in FIGS. 3A-E. In one embodiment, a light emitting source and automated probing device are used to measure the output of the formed solar cell structure 304 by use of various automated components adapted to make electrical contact with the junction box terminals 371, 372 (FIG. 3C) in the junction box 370. During testing, to assure that the solar cell structure 304 has desirable electrical characteristics, the active region(s) of the solar cell structure 304 are exposed to a known amount of light energy within a desired range of wavelengths. If the solar simulator module detects a defect in the measured output characteristics of the solar cell structure 304, the system controller 290 can take corrective actions or the solar cell structure 304 can be scrapped. If the output of the formed device meets the user defined requirements, a back surface of the solar cell structure 304 receives a label that denotes the actual measured electrical characteristics of the device, and the solar cell structure 304 is allowed to proceed to the next step in the solar cell fabrication process sequence 100. In one embodiment, multiple solar cell structures 304 can be tested at once, such as a 2.2×2.6 m (e.g., Gen 8.5) formed solar cell device that has been sectioned to form two or four smaller solar cell structures 304.

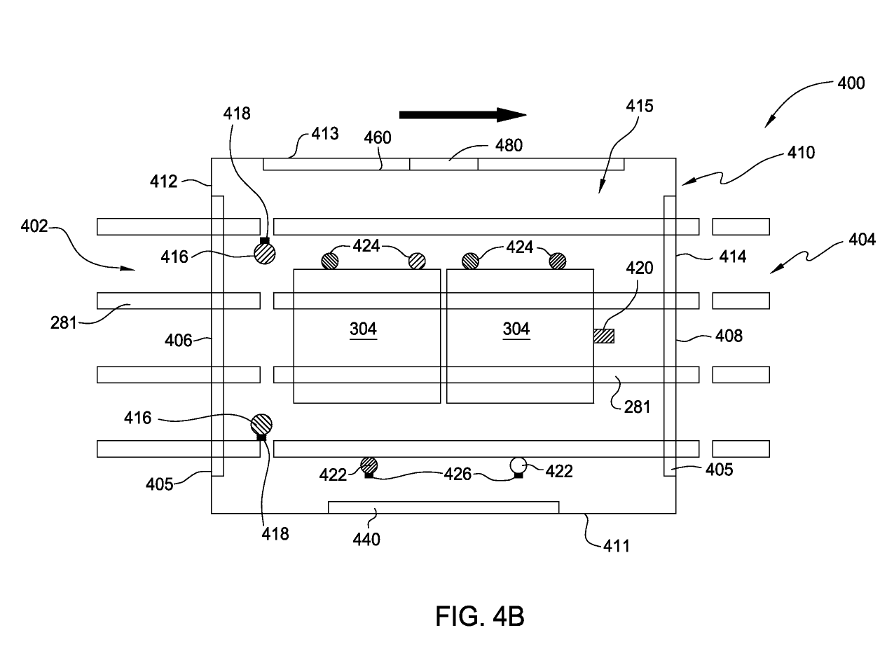

FIG. 4 is a schematic plan view of a solar simulator module 400 according to one embodiment of the present invention. The embodiment of the solar simulator module 400 depicted in FIG. 4 is configured for testing a full sized solar cell structure 304 (e.g. 2.2 m×2.6 m) or a half sized solar cell structure 304 (e.g. 2.2 m×1.3 m).

In one embodiment, the solar simulator module 400 comprises an enclosure 410 having walls 411-414 positioned around and enclosing a testing region 415 such that stray light and reflections do not affect the quality of the testing performed on the solar cell 300. The walls 411-414 of the enclosure 410 may be covered by a dark material, such as black felt, in order to minimize reflections in the testing region. In one embodiment, at least one of the walls 411-414 has one or more reflectors 405 disposed thereon. The solar simulator module 400 further comprises a light source 440, a positioning robot 460, and one or more probe nests 480, all disposed within the enclosure 410.

In one embodiment, the solar cell structure 304 is transferred into the testing region 415 from an input conveyor 402 via the automation device 281 prior to testing. Guide rollers 416 may be positioned to guide the edges of the solar cell structure 304 into the testing region 415. In one embodiment, the positions of the guide rollers 416 are adjustable to accommodate different sized solar cell structures 304. For instance, FIG. 4 depicts guide rollers 416 positioned to direct either a full sized solar cell structure 304 or a half sized solar cell structure 304 into the testing region 415. In one embodiment, the guide rollers 416 may be configured for manual adjustment. In another embodiment, the guide rollers 416 may be automatically adjusted via linear translation members 418, such as pneumatic cylinders, linear motors, or the like.

In one embodiment, an alignment mechanism 420 is disposed within the testing region 415 to detect when the solar cell structure 304 is correctly positioned on the automation device 281 for the next step in the testing process. The alignment mechanism 420 may comprise one or more position sensors for detecting a leading edge of the solar cell structure 304 as shown in FIG. 4. In one embodiment, one or more locating members 422 and one or more stop members 424 are disposed within the testing region 415 for positioning the solar cell structure 304. In one embodiment, the stop members 424 and the locating members 422 are adjustable. FIG. 4 depicts the locating members 422 and the stop members 424 located to position a full or half sized solar cell structure 304. In one embodiment, the stop members 424 may be manually adjusted into the appropriate position for the solar structure 304 size. The locating members 422 may be attached to linear translation members 426, such as pneumatic cylinders, linear motors, or the like. In this embodiment, the linear translation members 426 may cause the locating members 422 to push the solar cell structure 304 against the stop members 424. In another embodiment, both the stop members 424 and the locating members 422 are attached to linear translation members 426 for positioning the solar cell structure 304. The system controller 290 receives signals from the alignment mechanism 420 and sends signals to control the automation device 281 and the linear translation members 426 for correctly positioning the solar cell structure 304.

After testing is complete, the solar cell structure 304 may be transferred from the testing region 415 via the automation device 281 onto an output conveyor 404. In one embodiment, a slit 406 is disposed through the wall 412 adjacent the input conveyor 402, and a slit 408 is disposed through the wall 414 adjacent the output conveyor 404 to allow the transfer of the solar cell structure 304.

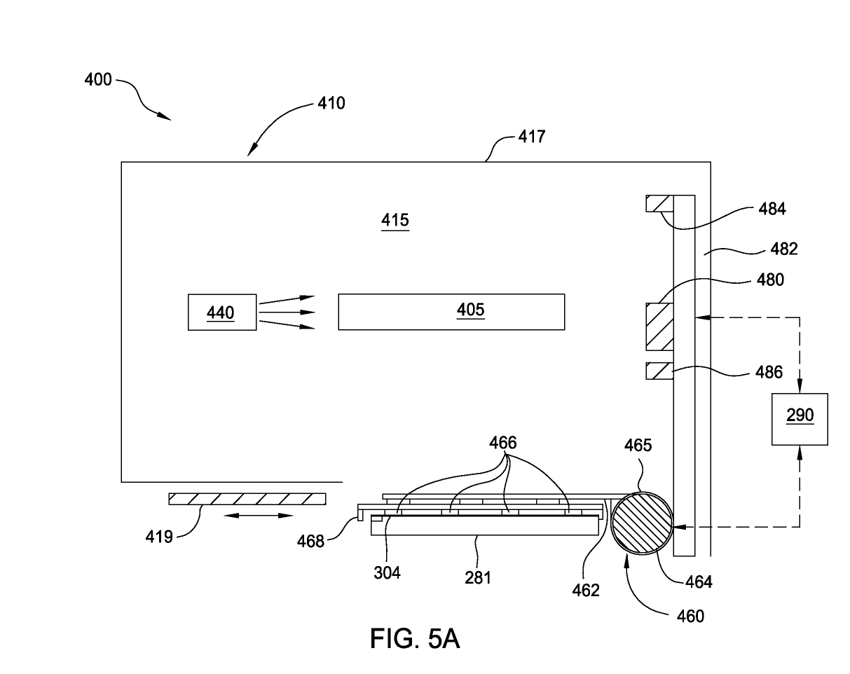

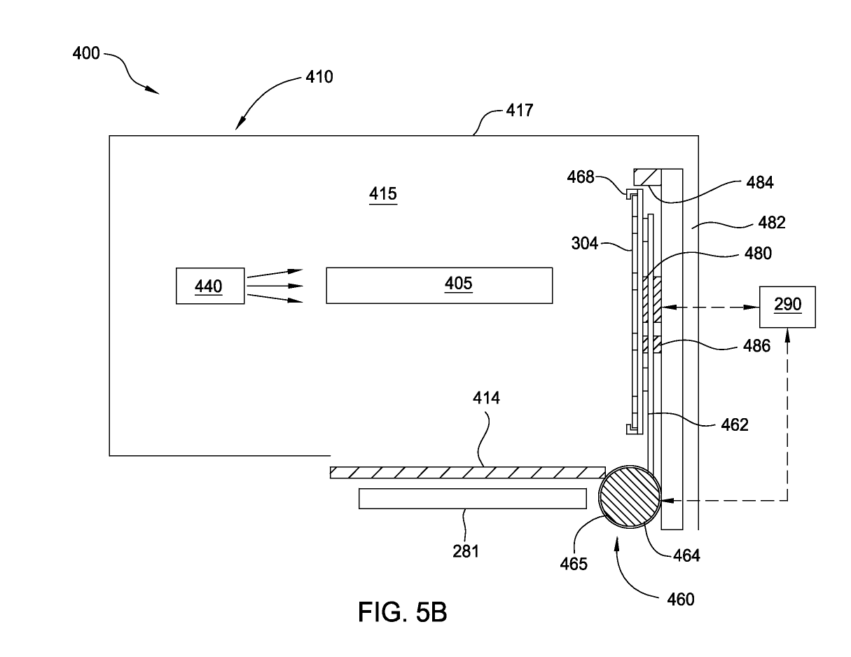

FIG. 5A is a schematic, cross-sectional view of the solar simulator module 400 taken along line 5-5 of FIG. 4A depicting the positioning robot 460 in a loading/unloading position. FIG. 5B is a schematic, cross-sectional view of the solar simulator module 400 taken along line 5-5 of FIG. 4 depicting the positioning robot 460 in a testing position.

In one embodiment, the positioning robot 460 comprises a gantry 462, a rotary actuator 464, a rotary brake 465, intermediate support elements 466, and edge support elements 468. The gantry 462 has a plurality of the intermediate support elements 466 and the edge support elements 468 attached thereto for grasping and holding the solar cell structure 304. In one embodiment, the intermediate support elements 466 are vacuum gripping elements for contacting and holding the back glass substrate 361 of the solar cell structure 304. The intermediate support elements 466 may be arranged into independently controlled zones to accommodate different sized solar cell structures 304. In one embodiment, the edge support elements 468 are pneumatically actuated swing-arm clamps for grasping the non-functional edges of the solar cell structure 304 during movement and testing procedures. Additionally, the edge support elements 468 may provide holding capability in the event suction is lost in the intermediate support elements 466. The function of the intermediate support elements 466 and the edge support elements 468 are controlled by the system controller 290.

In one embodiment, the rotary actuator 464 is a motor coupled to the gantry 462 for rotating the gantry 462 from a substantially horizontal, loading/unloading position to a substantially vertical testing position. The rotary brake 465 provides holding capability in the event power is lost during movement of the gantry 462. The function of the rotary actuator 464 may be controlled by the system controller 290.

In one embodiment, one or more probe nests 480 are attached to a vertical support member 482 for connecting to the electrical connection points of the junction box terminals 371, 372 of the solar cell structure 304 in the vertical, testing position. In one embodiment, the probe nest 480 further comprises self aligning tooling, which utilizes datum features of the junction box 370 to orient measurement probes within the probe nest 480 with the electrical connection points of the junction box terminals 371, 372. In one embodiment, the measurement probes are compliant pin members to provide additional tolerance and flexibility when connecting to the junction box terminals 371, 372.

In one embodiment, one or more reference cells 484 may be attached to the vertical support member 482 to receive light from the light source 440. The reference cell 484 may be used by the system controller 290 to monitor and control the output of the light source 440. In one embodiment, a plurality of reference cells 484 may be used to account for different p-n junctions in a multiple junction solar cell device, such as the tandem junction solar cell 300 illustrated in FIG. 3B. In one embodiment, one reference cell 484 may be configured to absorb an overall light spectrum, another reference cell 484 may be configured to absorb light solely in the red spectrum, and yet another reference cell 484 may be configured to absorb light solely in the blue spectrum. In one embodiment, the reference cell 484 may be used to calibrate the reference module 400, along with other devices, to qualify the output of the lamps and the environment of the testing module.

In one embodiment, one or more temperature sensors 486 may be mounted to the vertical support member 482. The temperature sensor 486 may be spring loaded to remain in contact with the back side of the solar cell structure 304 during the testing process.

In one embodiment, the light source 440 is oriented such that a flash of light is directed substantially horizontally toward the solar cell structure 304 held in the substantially vertical testing position by the positioning robot 460. The light source 440 may comprise one or more flash lamps configured to simulate the solar spectrum. In one embodiment, the light source 440 is configured to emit a flash of light for between about 9 ms to about 11 ms at an intensity from about 75 mW/cm² to about 125 mW/cm² toward the solar cell structure 304 being tested. In one embodiment, the light source 440 may include a filter (not shown) configured to remove wavelengths of light outside of the solar spectrum.

Conventional testing configurations generally require the light source to be in excess of 6.5 meters above a horizontally oriented 2.2 m×2.6 m solar cell structure during the testing. Thus, the horizontal configuration of the light source 440 toward a vertically oriented solar cell structure 304 improves the serviceability of the solar simulator module 400 because the light source is much lower to the ground and more readily accessible than conventional solar simulators having light sources vertically oriented above a horizontally oriented solar cell. Additionally, the overall footprint of the solar simulator module 400 may be substantially smaller than conventional solar simulators.

In one embodiment, the enclosure 410 further comprises a top member 417 and a bottom member 419 for fully enclosing the testing region 415 to prevent light from entering the enclosure 410 during testing of the solar cell structure 304. The bottom member 419 may be a retractable screen positioned in an automated fashion with an actuating device, such as a linear motor, pneumatic cylinder, or the like, over the bottom portion of the enclosure 410 to further prevent light outside the enclosure 410 from affecting the testing process. The bottom member 419 forms a portion of the testing region 415 that encloses the light source and solar cell structure 304 to provide light uniformity, intensity consistency, testing repeatability, and testing reliability. The top member 417 and the bottom member 419 may be fully lined with a dark material, such as black felt, to prevent unwanted reflections and enable a repeatable testing environment.

In one embodiment of the present invention, the testing region 415 is optimized to allow spacing between the solar cell structure 304 and the light source 440 to be between about 4.4 m and about 6.5 m and still achieve a Class A certification. In one embodiment, the reflectors 405 are configured within the testing region 415 to increase concentration and uniformity of light on the solar cell structure 304.

### Reference Module Design and Processes

Embodiments of the invention may further provide an apparatus and method of forming a reference module device that is able to help qualify solar cells that are formed on solar cell substrates that have a light receiving surface area that is up to at least about 5.7 m². In one embodiment, the reference module is able to qualify solar cells formed on a half sized panel or a quarter sized panel formed from substrates that are 2.2 m×2.6 m in size.

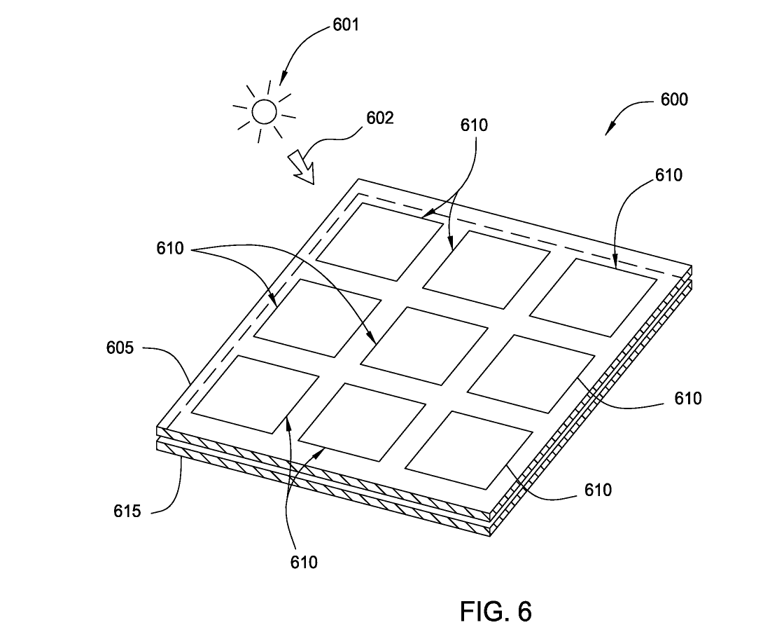

FIG. 6 illustrates one embodiment of a reference module 600 used to test one or more solar cell testing devices that are used to qualify one or more solar cells formed in a solar cell production line. In general, the reference module 600 contains an array of cells 610 that are positioned on a substrate 615 so that when the reference module 600 is positioned and oriented in a desired location at least a portion of the light energy 602 delivered from a light source 601 can be received by each of the cells 610. The substrate 615 can be formed form any desirable material that can support and retain the cells 610. In one embodiment, the substrate 615 is made from a material, such as a glass material or a metal. In one embodiment, the substrate 615 is either made from, or is at least partially covered with, a dielectric material that will provide electrical isolation between the metal connections formed on each of the cells 610, and between two or more cells 610.

The cells 610 in the reference module 600 may also be encapsulated between the substrate 615 and a cover 605 to prevent environmental attack of the cells 610 or other components in the reference module 600, which may degrade the long term performance of the reference module 600.

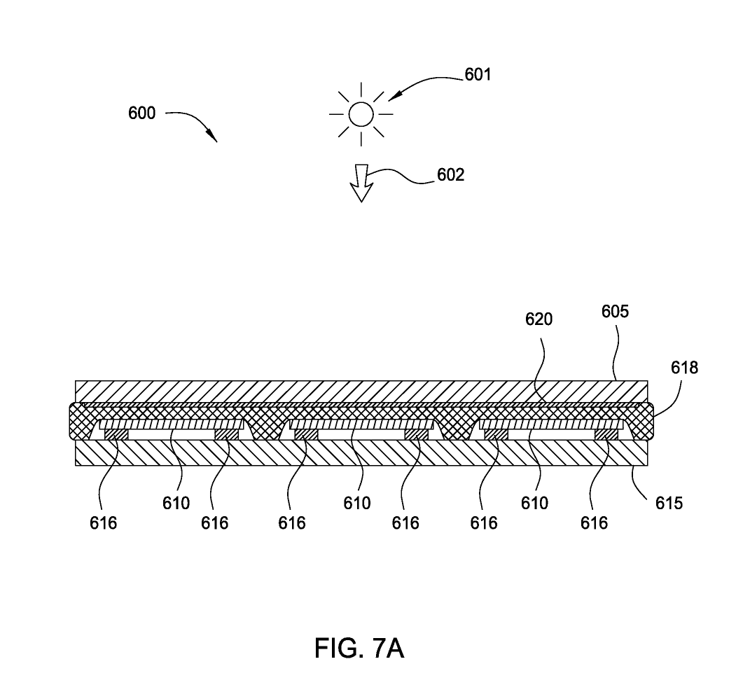

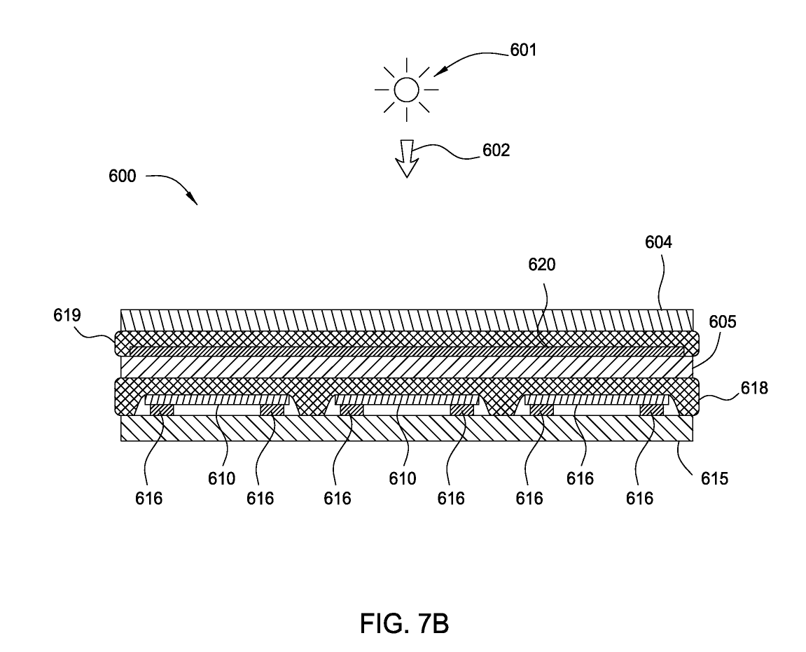

FIG. 7A is schematic cross-sectional side view of a reference cell 600 that has a layer of a polymeric material 618 that has been disposed between the cover 605 and the cells 610 and substrate 615 to isolate the cells 610 and other components from environmental attack. In one embodiment, the polymeric material 618 is a polyvinyl butyral (PVB) or ethylene vinyl acetate (EVA), which is sandwiched between the substrate 615 and the cover 605 using a process that provides heat and pressure to form a bonded and sealed structure. In general, the cover 605 and polymeric material 618 are made from a material that is optically transparent to allow the light delivered from the light source 601 to reach the cells 610. In one embodiment, the cover 605 is made of a glass, sapphire or quartz material. While not shown in FIGS. 6-7, in general, the reference module 600 also contains a support frame that is used to retain, support and mount one or more components in the reference module.

In one embodiment, as shown in FIG. 7A, each of the cells 610 are attached to the substrate 615 using the supports 616. In one embodiment, the one or more of the supports 616 are electrically conductive and are formed and positioned in a desirable pattern on the substrate 615 to electrically connect the cells 610 so that a desired power output can be achieved when a desired amount of light is delivered to the reference module 600. In one embodiment, all of the cells 610 are connected in series so that desired electrical output can be achieved. In cases where the cells have connections on both sides of the cell 610 then the supports 616 and/or other electrical connective elements (not shown) may be used to form a desirable connection path to deliver a desired power output.

In one embodiment, as shown in FIG. 7A, an optical filter 620 is positioned within the reference module 600 to block certain desired wavelengths of light from reaching the cells 610. This reference module 600 configuration thus allows more stable solar cells that have different absorption spectrums to be used in the formed reference module 600, rather than using a reference module that utilizes solar cells that have similar absorption spectrums but have varying electrical properties over time (e.g., silicon thin film solar cell). The more stable solar cells thus allow the reference module 600 to be a relatively unvarying “gold” calibration standard, which can be used in a solar cell qualification module to assure that it is functioning correctly without worrying about the reference module's shelf life or number of hours of light exposure.

It should be noted that the addition of any filtering type device over the cells 610 will reduce the amount of energy striking the surface of the cells. This affect can be compensated by increasing the total surface area of the cells 610, by use of more efficient cells 610 than the solar cell devices formed in the production line, and/or by correcting the systematic error by software in the solar cell qualification module. While the filter 620, shown in FIG. 7A, is positioned within the reference module 600, this configuration is not intended to be limiting as to the scope of the invention since the filter could also be affixed to the cover 605, it could be deposited on the cover 605, or the cover 605 could be altered by adding a doped impurity within the cover 605 material to provide a desirable optical filtration.

FIG. 7B illustrates another embodiment of the reference module 600 that is similar to the configuration illustrated in FIG. 7A, except the filter 620 has been positioned between a second cover 604 and a second layer of polymeric material 619 and the top surface of the cover 605, as shown. In general, the second cover 604 is made from a material that is optically transparent to allow the light delivered from the light source 601 to reach the cells 610. In one embodiment, the cover 604 is made of a glass, sapphire or quartz material.

In one embodiment, the optical filter 620 may be a band-stop or a notch type filter that is adapted to preferentially allow one or more ranges of wavelengths to be delivered to the cells 610. In another embodiment, the optical filter 620 may be a band-pass type filter. In some cases it is desirable to use a long-pass or short-pass filter to remove either the short or long wavelengths from being delivered to the cells 610. For example, the reference cell 600 and optical filter 620 may be configured to absorb light solely in the red spectrum or to absorb light solely in the blue spectrum.

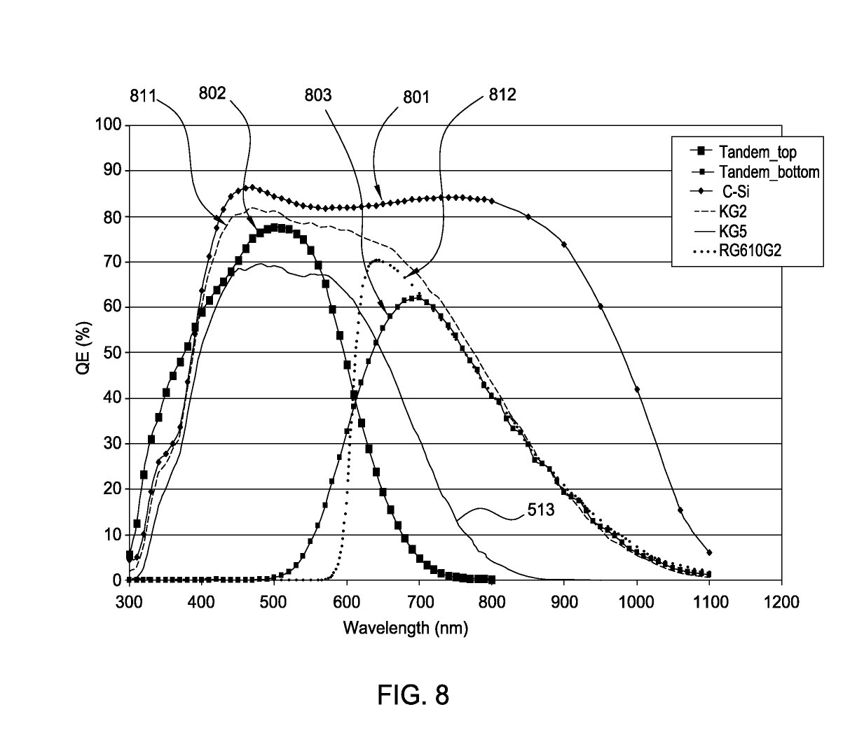

FIG. 8 is a plot of quantum efficiency versus wavelength for a typical crystalline solar cell (see plot 801), a top cell in a tandem junction silicon thin film solar cell (see plot 802) and a bottom cell in the tandem junction silicon thin film solar cell (see plot 803). FIG. 8 thus illustrates the difference in spectrum response for a crystalline solar cell and a tandem junction solar cell, and tends to illustrate why the use of an array of crystalline solar cells in place of a formed silicon thin-film solar cell will provide differing testing results when using similarly sized modules.

Also, as illustrated in FIG. 8, by selecting the right type of filter(s) the output of a crystalline solar cell, such as used in the reference module, can be matched to the output of an unfiltered tandem junction solar cell. Referring to spectrum response 811 illustrated in FIG. 8, in one case by use of a KG2 optical filter supplied from Barr Associates, Inc. of Westford, MA, the output of an array of crystalline solar cells can be used to match the output of an unfiltered tandem junction solar cell. In cases where it is desirable to qualify the output of a single junction silicon solar cell or a bottom cell in the tandem junction silicon thin film solar cell a filter that has a spectrum response 812, such as a RG610 optical filter supplied from Barr Associates can be used. In cases where it is desirable to qualify the output of only a top cell in a tandem junction silicon thin film solar cell a filter that has a spectrum response 813, such as a KG5 optical filter supplied from Barr Associates may be used.

In one embodiment, the cells 610 are crystalline silicon solar cells. In one case the cells 600 are each made from a 144 cm² crystalline silicon solar cell. However, the use of a crystalline silicon solar cell is not intended to be limiting as to the scope of the invention since the cells 610 could be formed from other materials, such as III-V type solar cells, thin film chalcogenide solar cells (e.g., CIGS, CdTe cells), photochemical type solar cells (e.g., dye sensitized), organic type solar cells or other similar solar cell devices as long as the electrical properties of the solar cell do not degrade at an undesirable rate. In one embodiment, the cells are single crystal silicon solar cells.

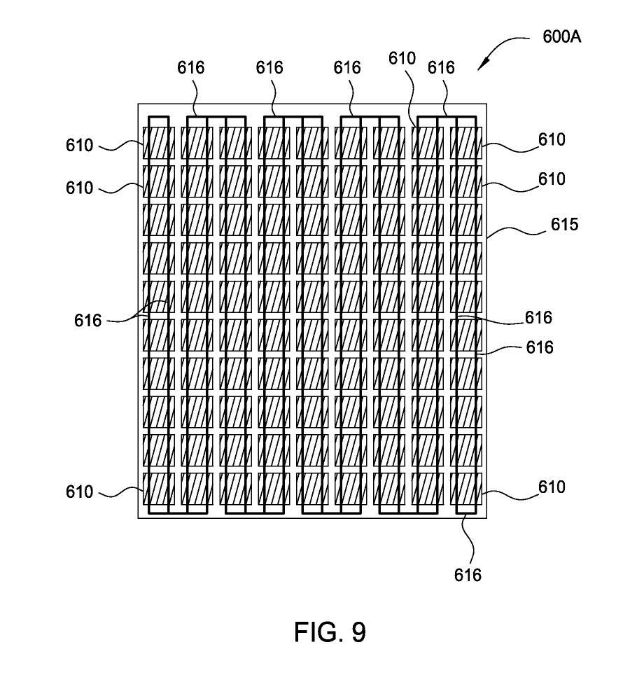

FIG. 9 is a plan view of one embodiment of a quarter panel sized (e.g., 1.1 m×1.3 m) reference module 600A that contains a 9×10 array of cells 610 disposed on a substrate 615 and interconnected using supports 616. In one embodiment, the cells 610 are 144 cm² crystalline silicon solar cells.

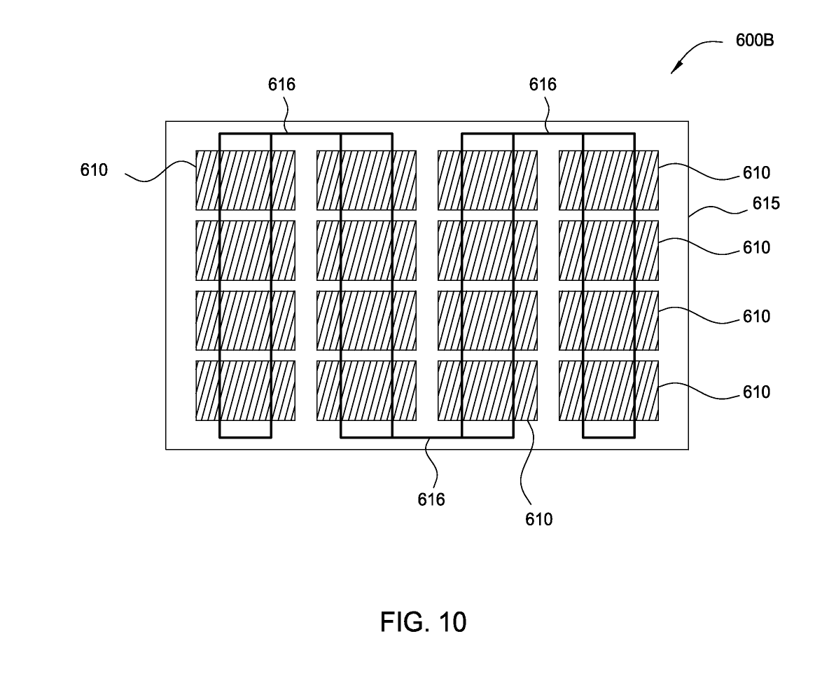

FIG. 10 is a plan view of one embodiment of a 0.53 m×0.53 m sized reference module 600B that contains a 4×4 array of cells 610 disposed on a substrate 615 and interconnected using supports 616. In one embodiment, the cells 610 are 144 cm² crystalline silicon solar cells. In one embodiment, a reference module 600 contains an array of crystalline silicon cells that are covered by a filter that is designed to match the quantum efficiency, short circuit current (I_{sc}), and fill factor for a quarter size amorphous-Si solar cell module. In one example, a 50 cm×50 cm reference module 600 contains sixteen 144 cm² crystalline solar cells that are each connected in series and have band pass filter in-between the light source and the cells.

In another embodiment of the invention, a method of making a reference module includes placing solar cells on a substrate, electrically connecting the solar cells to form a solar cell array, placing polymeric material over the array of solar cells, placing an optical filter over the polymeric material, and consolidating the substrate, the solar cell array, the polymeric material, and the optical filter, such as by laminating everything together. Additionally, the electrical connection between the solar cells may be provided by polymer supports connecting the solar cells to each other and the substrate. Alternative methods of making the reference module may include placing a second cover and second polymer material over an optical filter that is positioned between a top surface of the cover, and consolidating the solar cell array, the polymeric material, the cover, the optical filter, a second polymeric material, and a second cover. Other similar methods of making a reference module may be used to create the various embodiments described herein.

The design of the optical filter may be different for different solar cell fabs, depending on the type of solar cell device being manufactured, both structurally and materially. For example, the optical filter may be designed to have different properties for testing and calibrating the testing modules used to approve the production of single junction type solar cells versus tandem junction type solar cells. Additionally, the optical filter properties may also be designed for silicon type solar cells, thin film solar cells, microcrystalline silicon film (μc-Si) solar cells, amorphous silicon film (a-Si) solar cells, polycrystalline silicon film (poly-Si) solar cells such as copper indium diselenide (CIS), cadmium telluride (CdTe), copper indium gallium selenium (CIGS) type solar cells, single-crystalline type solar cells, or multicrystalline type solar cells, and single-crystalline thin film types such as gallium arsenide (GaAs). Moreover, the optical filter may be designed for flexible solar panels and various combinations of solar panels that may be manufactured.

Generally, the optical filter may be designed to match any type of solar cell. For example, the spectrum response of a bare crystalline silicon type solar cell that will be used in the reference can be measured and compared to the spectrum response of the solar cells manufactured along the production line. The spectrum response data from the solar cells used in the reference module are compared to the production solar cells. The difference in spectrum response data is then used to create an optical filter that will match the spectrum response of the combined optical filter and solar cells in the reference module to the production solar cells.

In some embodiments of the invention, the optical filter could be coated on glass or separate sheet by a PVD method. In one embodiment of the invention, a method for designing a reference module includes forming an array of solar cells, determining the absorption characteristics of the array of solar cells, determining the absorption characteristics of the type of solar cells to be manufactured, and designing an optical filter to be used with the array of solar cells such that the array of solar cells and optical filter match the current output of the type of solar cells to be manufactured.

In one embodiment of the invention, the reference module is designed to have an output current that matches the output current of the type of solar cells being manufactured. In solar cells, the surface area determines, among other variables, the amount of current output produced when the solar cells are exposed to light. Another variable that affects current output is the efficiency of the solar cell which will vary depending on the type of solar cell. For example, crystalline solar cells may have efficiencies of around 20% whereas thin-film solar cells may only have efficiencies around 9%. Another variable that affects current output is the optical filter type which may decrease the efficiency of the reference module.

Taken all together, embodiments of the invention may provide a long lasting reference module that will match the current output of the solar cells being manufactured to provide accurate calibration of a testing chamber. For example, in one embodiment of the invention, production solar cells may be of a thin-film type having a single cell area of 130 cm², such as a solar cell 1 cm wide by 130 cm long. One thin film type solar panel may have 106 such solar cells. The reference module may be designed to match the current output of the solar cell panel. In this example, the reference module may be a more efficient crystalline type solar cell having a cell size of 12 cm×12 cm or 144 cm², which when combined with an optical filter and a pre-determined number of reference solar cells connected together to create the array of solar cells in the reference module, will match the current output of the thin film solar panel of 106 solar cells.

While the foregoing is directed to embodiments of the present invention, other and further embodiments of the invention may be devised without departing from the basic scope thereof, and the scope thereof is determined by the claims that follow.

1. A device used to qualify a solar cell testing module, comprising:
a substrate;
a plurality of solar cells disposed over a surface of the substrate; and
an optical filter disposed over at least one of the plurality of solar cells, wherein the optical filter is adapted to preferentially transmit a desired range of wavelengths of light.

2. The device according to claim 1, wherein the solar cells are attached to the substrate using a plurality of supports.

3. The device according to claim 2, further comprising:
a cover encapsulating the solar cells; and
a layer of polymeric material disposed between the cover and the substrate.

4. The device according to claim 3, wherein the polymeric material is further disposed between the solar cells.

5. The device according to claim 3, wherein the polymeric material isolates the solar cells and supports from environmental attack.

6. The device according to claim 3, wherein the polymeric material is between the substrate and the cover to form a bonded and sealed structure.

7. The device according to claim 3, wherein the cover and polymeric material is made from optically transparent material.

8. The device according to claim 3, wherein the polymeric material comprises polyvinyl butryal (PVB) or ethylene vinyl acetate (EVA).

9. The device according to claim 3, wherein the cover comprises glass, sapphire, or quartz material.

10. The device according to claim 3, wherein the supports are electrically conductive and are positioned on the substrate to electrically connect the solar cells such that a desired power output may be achieved when a desired amount of light is delivered to the reference module.

11. The device according to claim 10, wherein the solar cells are connected in series.

12. The device according to claim 3, wherein the optical filter is positioned between the cover and the solar cells.

13. The device according to claim 3, wherein the optical filter is affixed to the cover.

14. The device according to claim 3, wherein the optical filter is deposited on the cover.

15. The device according to claim 3, wherein the optical filter is positioned between a top surface of the cover and a second layer of polymeric material and a second cover.

16. The device according to claim 1, wherein the substrate is made from glass or metal.

17. A device used to qualify a solar cell testing module, comprising:
a substrate;
a plurality of solar cells disposed over a surface of the substrate; and
a cover encapsulating the solar cells, the cover further comprising an optical filter, wherein the optical filter is adapted to preferentially transmit a desired range of wavelengths of light.

18. The device according to claim 17, wherein the solar cells are attached to the substrate using a plurality of supports.

19. The device according to claim 17, further comprising:
a layer of polymeric material disposed between the cover and the substrate.

20. The device according to claim 17, wherein the cover comprises a doped impurity to provide a desirable optical filtration.

21. The device according to claim 19, wherein the polymeric material is between the substrate and the cover to form a bonded and sealed structure.

22. A method of making a reference module, comprising:
placing a plurality of solar cells on a substrate;
electrically connecting the solar cells to form a solar cell array;
placing a polymeric material over the array of solar cells;
placing an optical filter over the polymeric material; and,
consolidating the substrate, the solar cell array, the polymeric material, and the optical filter

23. The method of claim 22, wherein the consolidating comprises laminating the solar cell array, the polymeric material, and the optical filter.

24. A system for qualifying solar cell devices, comprising:
a plurality of solar cell processing chambers that are adapted to form at least a portion of a solar cell device on a substrate;
a solar simulator module having a testing assembly that is adapted to measure the electrical characteristics of a solar cell device formed on the substrate when exposed to a known amount of light delivered from a lamp; and
a reference module that is used to calibrate the testing assembly, wherein the reference module comprises:
a substrate;
a plurality of solar cells disposed over a surface of the substrate;
an optical filter disposed over at least one of the plurality of solar cells, wherein the optical filter is adapted to preferentially transmit a desired range of wavelengths of light.

25. A method of qualifying a solar cell testing process, comprising:
forming a first type of solar cell device;
qualifying the electrical characteristics of the formed first type of solar cell device in a solar simulator module by measuring the electrical output of the first type of solar cell device when a known amount of optical energy is delivered to a surface of the first type of solar cell device;
forming a reference module that comprises:
a substrate;
two or more second type of solar cells disposed over a surface of the substrate;
an optical filter disposed over at least one of the two or more second type of solar cells;
qualifying the solar simulator by measuring the electrical output of the reference module when the same known amount of optical energy is delivered to a surface of the two or more second type of solar cells and comparing the measured result with a previous measured result performed using the reference module.
